(19) United States
(12) Patent Application Publication
(10) Pub. No.: US 2016/0260473 A1
(43) Pub. Date: Sep. 8, 2016

(54) SEMICONDUCTOR MEMORY DEVICE

(71) Applicant: Kabushiki Kaisha Toshiba, Tokyo (JP)

(72) Inventor: Toshikazu Fukuda, Yokohama Kanagawa (JP)

(21) Appl. No.: 14/843,633

(22) Filed: Sep. 2, 2015

(30) Foreign Application Priority Data
Mar. 5, 2015 (JP) 2015-043928

(51) Int. Cl. G11C 11/419

(52) U.S. Cl. CPC G11C 11/419

(57) ABSTRACT

According to one embodiment, a semiconductor memory device includes: a memory cell array including an SRAM cell; and a first voltage generator including first and second circuits. The first and second circuits include a diode-connected first transistor and a diode-connected second transistor, respectively. A driving capability of the first transistor is different from a driving capability of the second transistor. When the SRAM cell is in a standby state, the first voltage generator applies a second voltage or a third voltage to the SRAM cell via the first circuit or the second circuit.

### CROSS-REFERENCE TO RELATED APPLICATIONS

This application is based upon and claims the benefit of priority from Japanese Patent Application No. 2015-043928, filed Mar. 5, 2015, the entire contents of which are incorporated herein by reference.

### FIELD

Embodiments described herein relate generally to a semiconductor memory device.

### BACKGROUND

As a semiconductor memory device, an SRAM (static random access memory) is known. In the SRAM, it is important to reduce a leakage current in the SRAM in a data retention state in order to reduce power consumption.

### BRIEF DESCRIPTION OF THE DRAWINGS

FIG. 1 is a block diagram of a semiconductor memory device according to a first embodiment;

FIG. 2 is a timing chart illustrating potentials of interconnects in a first voltage generator provided in the semiconductor memory device according to the first embodiment;

FIG. 3 is a graph illustrating a relation between a current and a voltage at a node VSINT provided in the semiconductor memory device according to the first embodiment;

FIG. 4 is a graph illustrating the relation between the current and the voltage at the node VSINT;

FIG. 5 is a block diagram of a semiconductor memory device according to a second embodiment;

FIG. 6 is a timing chart illustrating potentials of interconnects in a second voltage generator provided in the semiconductor memory device according to the second embodiment;

FIG. 7 is a graph illustrating a relation between a current at a node VDINT and a voltage resulting from subtraction of a voltage at the node VDINT from VDD provided in the semiconductor memory device according to the second embodiment;

FIG. 8 is block diagram of a semiconductor memory device according to a third embodiment;

FIG. 9 is a timing chart illustrating potentials of interconnects in a first voltage generator and a second voltage generator provided in the semiconductor memory device according to the third embodiment;

FIG. 10 is block diagram of a semiconductor memory device according to a fourth embodiment;

FIG. 11 is a timing chart illustrating potentials of interconnects in a first voltage generator and a voltage detector provided in the semiconductor memory device according to the fourth embodiment;

FIG. 12 is block diagram of a semiconductor memory device according to a fifth embodiment;

FIG. 13 is a timing chart illustrating potentials of interconnects in a first voltage generator and a timer circuit provided in the semiconductor memory device according to the fifth embodiment;

FIG. 14 is block diagram of a semiconductor memory device according to a sixth embodiment;

FIG. 15 is a timing chart illustrating potentials of interconnects in a second voltage generator and a voltage detector provided in the semiconductor memory device according to the sixth embodiment; and

FIG. 16 is a block diagram of a semiconductor memory device according to a modification of the first embodiment.

### DETAILED DESCRIPTION

In general, according to one embodiment, a semiconductor memory device includes: a memory cell array; a first power supply line; a second power supply line; a first voltage generator; and a first interconnect. The memory cell array includes an SRAM (static random access memory) cell. The first power supply line applies a low-voltage-side power supply voltage to the SRAM cell. The second power supply line applies a high-voltage-side power supply voltage that is higher than the low-voltage-side power supply voltage to the SRAM cell. The first voltage generator applies a voltage to one of the first and second power supply lines. The first interconnect applies a first voltage to the first voltage generator. The first voltage generator includes: a first circuit; a second circuit; and a first switch circuit capable of switching between coupling of the first circuit between the one of the first and second power supply lines and the first interconnect and coupling of the second circuit between the one of the first and second power supply lines and the first interconnect. The first circuit includes a diode-connected first transistor coupled between the one of the first and second power supply lines and the first interconnect. The second circuit includes a diode-connected second transistor coupled between the one of the first and second power supply lines and the first interconnect. A driving capability of the first transistor is different from a driving capability of the second transistor. When the SRAM cell is in an operating state, the first voltage generator applies the first voltage to the one of the first and second power supply lines. When the SRAM cell is in a wait state, the first voltage generator applies the first voltage to the one of the first and second power supply lines via the first circuit or the second circuit to apply a second voltage or a third voltage to the one of the first and second power supply lines.

### 1. First Embodiment

A semiconductor memory device according to a first embodiment will be described. A case where the semiconductor memory device is an SRAM (static random access memory) will be described by way of example.

1.1 Configuration of the SRAM

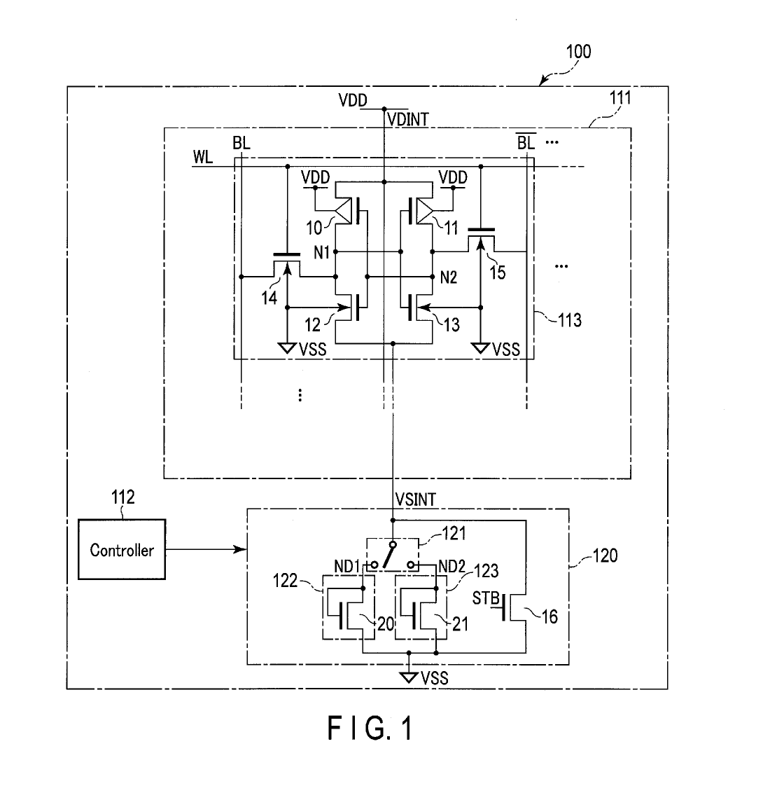

First, a configuration of the SRAM will be described using FIG. 1. As depicted in FIG. 1, an SRAM 100 includes a memory cell array 111, a controller 112, and a first voltage generator 120.

The memory cell array 111 includes a plurality of SRAM cells 113 arranged in a matrix. The SRAM cells 113 arranged in the same row are connected in common to the same word line WL. The SRAM cells 113 arranged in the same column are connected to the same bit line pair BL and /BL. The number of SRAM cells 113 is optional.

Each of the SRAM cells 113 includes two p-channel MOS transistors 10 and 11 and four n-channel MOS transistors 12 to 15. The transistors 10 and 11 function as load transistors. The transistors 12 and 13 function as driver transistors. The transistors 14 and 15 function as transfer gate transistors.

The transistor 10 connects to a node N2 at a gate of the transistor 10, to a high-voltage-side power supply voltage node VDINT at a source of the transistor 10, and to a node N1 at a drain of the transistor 10. The transistor 11 connects to the node N1 at a gate of the transistor 11, to the node VDINT at a source of the transistor 11, and to the node N2 at a drain of the transistor 11. For example, a power supply voltage VDD (for example, 3.3 V) is applied to back gates of the transistors 10 and 11.

The transistor 12 connects to the node N2 at a gate of the transistor 12, to the node N1 at a drain of the transistor 12, and to a low-voltage-side power supply voltage node VSINT at a source of the transistor 12. The low-voltage-side power supply voltage node VSINT is applied a power supply voltage lower than the power supply voltage applied to the high-voltage-side power supply voltage node VDINT. The transistor 13 connects to the node N1 at a gate of the transistor 13, to the node N2 at a drain of the transistor 13, and to the node VSINT at a source of the transistor 13. A ground voltage VSS (for example, 0 V) is applied to back gates of the transistors 12 and 13.

The transistors 10 and 12 form a first inverter. The transistors 11 and 13 form a second inverter. The node N1 is connected to an output of the first inverter and an input of the second inverter. The node N2 is connected to an input of the first inverter and an output of the second inverter. Therefore, inverted data of data held at the node N1 is held at the node N2. Specifically, for example, when the node N1 is provided with “H” level data, the node N2 is provided with “L” level data.

The transistor 14 connects to the word line WL at a gate of the transistor 14, to the node N1 at one of a source and a drain of the transistor 14, and to the bit line BL at the other of the source and the drain. The transistor 15 connects to the word line WL at a gate of the transistor 15, to the node N2 at one of a source and a drain of the transistor 15, and to the bit line /BL at the other of the source and the drain. The ground voltage VSS is applied to back gates of the transistors 14 and 15.

For example, in a write operation, the transistors 14 and 15 connected to the selected word line WL are set to an on state. “H” level data or “L” level data is provided to the first inverter via the bit line BL. Inverted data of the data provided to the first inverter is provided to the second inverter via the bit line /BL.

The controller 112 controls the first voltage generator 120. More specifically, the controller 112 sets a signal STB and a switch circuit 121 according to the state of the memory cell array 111. The signal STB is, for example, set to the “H” level in a state of write operation or read operation for the memory cell array 111 (hereinafter referred to as an “operating state”) and to the “L” level in a state where data is held in the memory cell array 111 (hereinafter referred to as a “standby state”).

The first voltage generator 120 applies voltages needed for the operating state and the standby state to the memory cell array 111 via the node VSINT. The first voltage generator 120 includes an n-channel MOS transistor 16, a switch circuit 121, a first driving circuit 122, and a second driving circuit 123.

The signal STB is input to a gate of the transistor 16, a drain of the transistor 16 is connected to the node VSINT, and the ground voltage VSS is applied to a source of the transistor 16 via a ground node. For example, when the transistor 16 is in the on state, the first voltage generator 120 applies the VSS to the node VSINT.

The switch circuit 121 receives an instruction from the controller 112 to switch to connection between the node VSINT and a node ND1 connected to the first driving circuit 122 or connection between the node VSINT and a node ND2 connected to the second driving circuit 123.

The first driving circuit 122 and the second driving circuit 123 apply a low-voltage-side power supply voltage to the node VSINT. The first driving circuit 122 includes an n-channel MOS transistor 20. The transistor 20 is diode-connected and connects to the node ND1 at a gate and a drain of the transistor 20. The VSS is applied to a source of the transistor 20 via the ground node. The second driving circuit 123 includes an n-channel MOS transistor 21. The transistor 21 is diode-connected and connects to the node ND2 at a gate and a drain of the transistor 21. The VSS is applied to a source of the transistor 21 via the ground node.

The first driving circuit 122 and the second driving circuit 123 are different from each other in current driving capability. Specifically, the transistors 20 and 21 are different from each other in the relation between a drain current and a drain voltage due to a difference in gate width, gate length, or film thickness of a gate oxide film between the transistors 20 and 21. In other words, compared to diodes, the transistors 20 and 21 are different from each other in current-voltage characteristic at a forward bias.

In the present embodiment, a case will be described in which, when the first driving circuit 122 and the second driving circuit 123, that is, the diode-connected transistors 20 and 21, are compared with each other, a larger amount of drain current flows through the transistor 20 at the same voltage (the transistor 20 has a higher current driving capability). Specifically, the gate widths W of the transistors 20 and 21 are in a relation such that “the gate width W1 of the transistor 20”>“the gate width W2 of the transistor 21”.

The driving circuits with “different current driving capabilities” as used herein include not only a case where the unitary transistors included in the driving circuits are different from each other in characteristics as in the case of, for example, the first driving circuit 122 and the second driving circuit 123, but also a case where current paths to which a plurality of diode-connected transistors are connected are different from each other in current-voltage characteristic. For example, a driving circuit with a current path in which two transistors with the same characteristics are connected together in series is different in current driving capability and current-voltage characteristic from a driving circuit with a current path in which three transistors with the same characteristics are connected together in series. A plurality of transistors may be connected in parallel with one current path, or one current path may connect to both a plurality of transistors connected in series and a plurality of transistors connected in parallel. Moreover, for example, a current path to which the transistor 16 is connected is different in current-voltage characteristic (in current driving capability) from a current path to which the first and second driving circuits are connected. When the transistor 16 is in the on state, the current driving capability is high.

1.2 Voltages in the Operating State and the Standby State

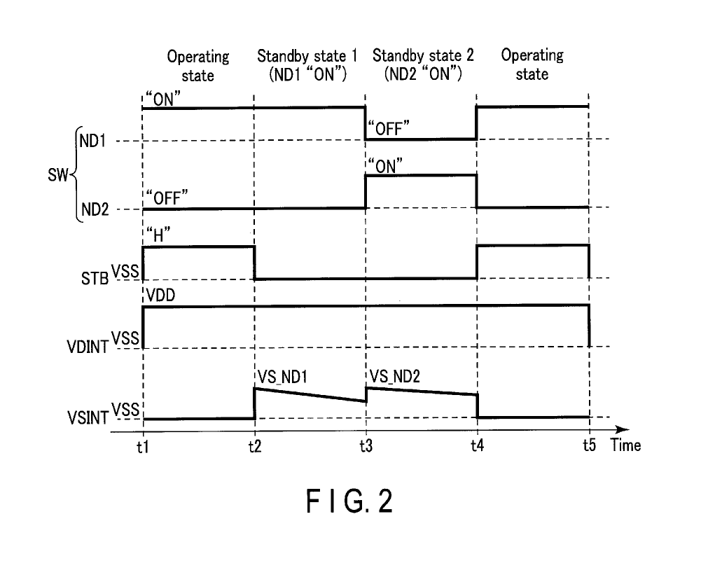

Next, the voltages of the interconnects in the operating state and the standby state will be described using FIG. 2. In the example in FIG. 2, the SRAM 100 is in the operating state (for example, during data write or read) during points in time t1 to t2 and during points in time t4 to t5, and is in the standby state during points in time t2 to t4.

First, at point in time t1, the controller 112 sets the signal STB to the “H” level to turn on the transistor 16 as depicted in FIG. 2. Thus, the first voltage generator 120 applies the VSS (for example, 0 V) to the node VSINT. The controller 112 selects the node ND1 in the switch circuit 121. However, a current flowing from the memory cell array 111 to the ground node flows mostly through a current path via the transistor 16 because the transistor 16 is in the on state. Therefore, in the switch circuit 121, the node ND2 may be selected or neither the node ND1 nor the node ND2 may be selected.

Then, at point in time t2, the SRAM 100 is set to the standby state. In response, the controller 112 sets the signal STB to the “L” level to set the transistor 16 to the off state. Consequently, a current flows from the node VSINT to the ground node via the node ND1 (first driving circuit 122). At this time, a voltage drop at the transistor 20 sets the potential of the node VSINT to VS_ND1. When a potential difference in the memory cell array 111 (the potential difference between the node VDINT and the node VSINT) is designated as Vcell, and the minimum value of Vcell needed for the SRAM to hold data is designated as Vcell_min (for example, 0.8 V), the voltage of the node VDINT (=VDD) and the voltage VS_ND1 are in a relation (VDD−VS_ND1)=Vcell>Vcell_min.

During points in time t2 to t3, the temperature of the memory cell array 111 (hereinafter referred to as the “internal temperature”) decreases. When the memory cell array 111 is set to the operating state, the internal temperature rises and increases the power consumption. Then, when the memory cell array 111 is set to the standby state, the internal temperature gradually lowers. The lowering internal temperature reduces a leakage current in the transistor forming the SRAM cell 113, while increasing the Vcell. The Vcell is in a relation VDD−VS_ND1=Vcell, and thus, VS_ND1 decreases consistently with increasing Vcell.

At point in time t3, the controller 112 uses, for example, a change in internal temperature as a trigger (specific examples will be described below in a fourth to a sixth embodiments) to select the node ND2 (second driving circuit 123) in the switch circuit 121. Therefore, a current flows from the node VSINT to the ground node via the node ND2. A voltage drop at the transistor 21 sets the potential of the node VSINT to VS_ND2. As is the case with VS_ND1, the voltage of the node VDINT and the voltage VS_ND2 are in a relation (VDD−VS_ND)=Vcell>Vcell_min. The VS_ND1 and the VS_ND2 are in a relation VS_ND1<VS_ND2 at the same internal temperature. During points in time t3 to t4, the VS_ND2 decreases consistently with the internal temperature.

Then, at point in time t4, the SRAM 100 is set to the operating state. In response, the controller 112 sets the signal STB to the “H” level and the first voltage generator 120 applies the VSS to the node VSINT as is the case with point in time t1. The controller 112 selects, for example, the node ND1 in the switch circuit 121.

1.3 Effect of the Present Embodiment

The configuration according to the present embodiment enables a reduction in power consumption. The present effect will be described below.

To hold the data of the memory cell array 111 in the standby state, the potential difference between the node VDINT and the node VSINT needs to be set equal to or higher than Vcell_min (for example, 0.8 V). Thus, even in the standby state, a leakage current flows through the memory cell array 111, leading to power consumption. However, the voltage needed in the standby state is lower than the voltage needed in the operating state. Consequently, the Vcell in the standby state is decreased to enable a reduction in leakage current. In this case, for example, when the voltage of the node VSINT is increased to reduce the Vcell, at the n-channel MOS transistors 12 to 15 in the SRAM cell 113 increase in the voltage of the source (node VSINT), while relatively decreasing in the voltage of back gate (for example, the VSS). Therefore, a substrate bias effect is exerted to increase the threshold voltage of the transistor. Therefore, the leakage current in the n-channel MOS transistor can be reduced.

However, the leakage current and the Vcell change according to the internal temperature. Specifically, a rising internal temperature increases the leakage current, while reducing the Vcell. Thus, when the voltage of the node VSINT is set, it is necessary to set Vcell>Vcell_min at the upper limit temperature (for example, 125° C.) of an operating guarantee temperature range. However, the internal temperature in the standby state is lower than the upper limit temperature in substantially all cases. Hence, the Vcell is higher than the potential difference set in connection with the upper limit temperature. This hinders a reduction in leakage current based on a decrease in Vcell. Moreover, a lowering internal temperature leads to an increase in Vcell and thus a decrease in the voltage of the node VSINT. This hinders a reduction in leakage current based on the substrate bias effect.

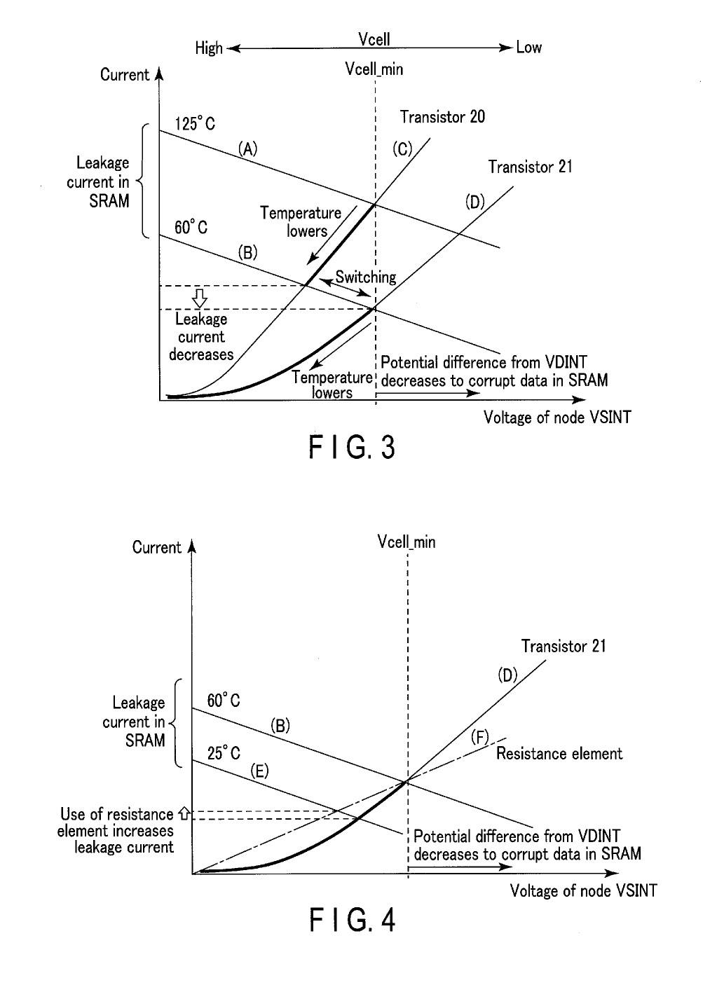

In contrast, in the present embodiment, the first voltage generator includes the plurality of driving circuits with the different current driving capabilities in order to control the voltage of the node VSINT in the standby state. The driving circuits are used in a switching manner to enable an effective reduction in leakage current and thus in power consumption even when the internal temperature changes. This effect will be described using FIG. 3.

FIG. 3 illustrates a relation between the voltage and the current at the node VSINT. As depicted in FIG. 3, Graph (A) illustrates a relation between the leakage current in the memory cell array 111 and the voltage of the node VSINT at an internal temperature of 125° C. Graph (B) illustrates a relation between the leakage current in the memory cell array 111 and the voltage of the node VSINT at an internal temperature of 60° C. As illustrated in Graphs (A) and (B), the leakage current decreases with increasing voltage of the node VSINT, that is, decreasing Vcell. The leakage current increases consistently with the internal temperature.

Graph (C) illustrates a current-voltage characteristic of the diode-connected transistor 20. Graph (D) illustrates a current-voltage characteristic of the diode-connected transistor 21.

For example, when the transistor 20 is selected at an internal temperature of 125° C., an intersection point between Graph (A) and Graph (C) serves as an operating point for the SRAM. For example, when the transistor 21 is selected at an internal temperature of 60° C., an intersection point between Graph (B) and Graph (D) serves as an operating point for the SRAM. Therefore, the relation between the internal temperature and each of the leakage current and the voltage of the node VSINT is as illustrated by thick solid line portions of Graph (C) and Graph (D).

In the example in FIG. 3, while the internal temperature is, for example, between 60° C. and 125° C., the controller 112 selects the transistor 20 (first driving circuit 122). Consequently, even at an internal temperature of 125° C., a potential difference of Vcell_min or higher is applied to the memory cell array 111. The voltage of the node VSINT decreases consistently with the internal temperature. When the internal temperature reaches 60° C., the controller 112 switches the transistor 20 to the transistor 21 (second driving circuit 123). Then, due to the difference in current driving capability between the transistors 20 and 21, the voltage of the node VSINT increases. Thus, the use of the transistor 21 enables a reduction in leakage current compared to the use of the transistor 20. For example, the controller 112 has a high internal temperature immediately after the controller 112 has shifted from the operating state to the standby state, and thus selects the transistor 20. Then, in the standby state, when the internal temperature decreases down to 60° C., the controller 112 switches the transistor 20 to the transistor 21. Accordingly, even when the internal temperature decreases, the leakage current can be effectively reduced, in turn reducing the power consumption.

Moreover, in the present embodiment, the driving circuits with the different current driving capabilities are used in a switching manner to enable a reduction in a variation in the voltage of the node VSINT caused by the internal temperature. Furthermore, the voltage of the node VSINT can remain the same even at different internal temperatures. For example, in FIG. 3, the transistor 20 is switched to the transistor 21 to allow the voltage of the node VSINT at 60° C. to remain the same as the voltage of the node VSINT at 125° C. Thus, a variation (decrease) in the voltage of the node VSINT caused by a decrease in internal temperature can be suppressed. This improves the effect of enabling a reduction in leakage current based on the substrate bias effect particularly at low temperature, leading to a reduction in power consumption.

Moreover, the present embodiment uses the diode-connected transistor to enable a higher reduction in leakage current than, for example, a case where a resistance element is used. For example, as depicted in FIG. 4, in a comparison of the transistor 21 with a resistance element (Graph (F)) with such a characteristic as passes through the intersection point between Graph (B) and Graph (D), for example, the amount of leakage current at 25° C. is larger in the case of the resistance element. This is due to a difference in current-voltage characteristic between the resistance element and the transistor. When the resistance element is used, the current exhibits a linear characteristic proportional to the voltage as illustrated in Graph (F). In contrast, when the transistor is used, the current exhibits a nonlinear characteristic as illustrated in Graph (D) in FIG. 4. Thus, the use of the transistor improves the effect of enabling a reduction in leakage current even at a low internal temperature, leading to a reduction in power consumption.

Moreover, in the present embodiment, for example, when a power supply with a fixed capacity such as a battery is used to hold data for a long period of time, the data holding time can be extended. For example, a lasting standby state causes the internal temperature to be kept in a low temperature state of 60° C. or lower. In such a case, the configuration according to the present embodiment switches to the driving circuit optimum for the current internal temperature, enabling a reduction in leakage current and thus in power consumption. Therefore, the fixed capacity of the power supply allows the data holding time to be extended.

In the present embodiment, the first voltage generator 120 has two driving circuits but may have three or more driving circuits as long as the driving circuits have different current driving capabilities.

Moreover, the switch circuit 121 selects one of the nodes ND1 and ND2. However, the nodes ND1 and ND2 may include separate switch elements. In this case, the nodes ND1 and ND2 may be simultaneously selected.

Moreover, the first driving circuit 122 and the second driving circuit 123 may each have two or more transistors.

Moreover, the first voltage generator 120 has a current path via the transistor 16 in the operating state. However, this current path may be omitted, and a current path via the transistor 16 may be provided with a driving circuit different from the first and second driving circuits in current driving capability. Even in the operating state, the signal STB may be at the “L” level.

Moreover, the first voltage generator is connected to the ground node, and the VSS is applied to the first voltage generator. However, the first voltage generator may be applied to a node at a potential different from the VSS.

### 2. Second Embodiment

Next, a semiconductor memory device according to a second embodiment will be described. In the present embodiment, the node VDINT includes a voltage generator. Only differences from the first embodiment will be described below.

2.1 Configuration of the SRAM

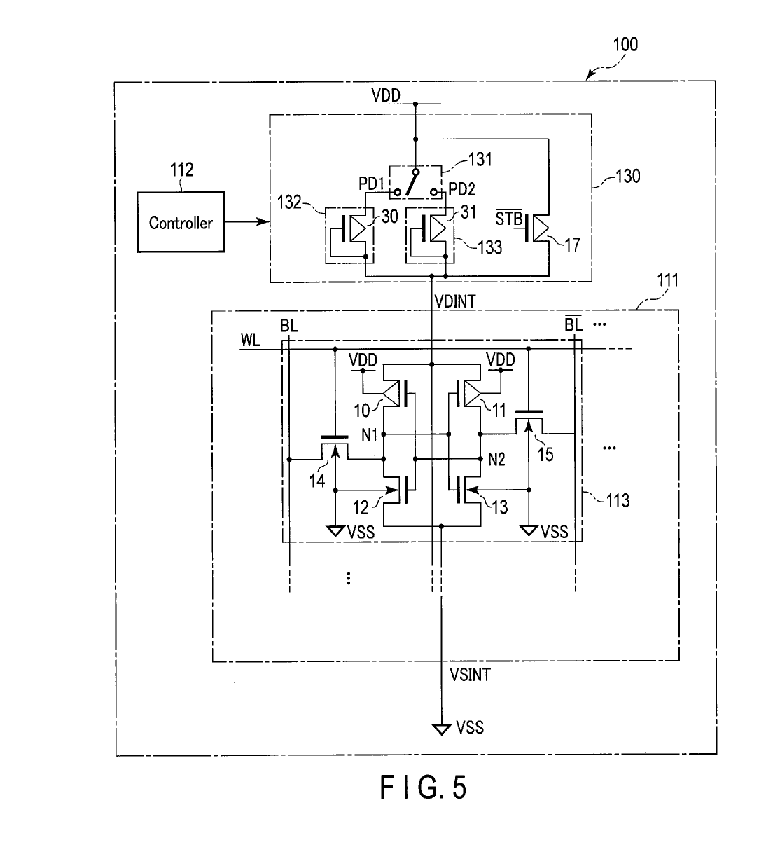

A configuration of the SRAM 100 according to the present embodiment will be described using FIG. 5.

As depicted in FIG. 5, the SRAM 100 includes a second voltage generator 130.

The second voltage generator 130 applies voltages needed for the operating state and the standby state to the memory cell array 111 via the node VDINT. The second voltage generator 130 includes a p-channel MOS transistor 17, a switch circuit 131, a third driving circuit 132, and a fourth driving circuit 133.

The signal /STB is input to a gate of the transistor 17, the power supply voltage VDD is applied to a source of the transistor 17, and a drain of the transistor 17 is connected to the node VDINT. For example, the signal /STB is at the “L” level in the operating state and is at the “H” level in the standby state.

The switch circuit 131 receives an instruction from the controller 112 to switch to connection between a power supply node that transfers the VDD and a node PD1 connected to the third driving circuit 132 or connection between the power supply node that transfers the VDD and a node PD2 connected to the fourth driving circuit 133.

The third driving circuit 132 and the fourth driving circuit 133 apply a high-voltage-side power supply voltage to the node VDINT. The third driving circuit 132 includes a p-channel MOS transistor 30. The transistor 30 is diode-connected and connects to the node PD1 at a source of the transistor 30 and to the node VDINT at a gate and a drain of the transistor 30. The fourth driving circuit 133 includes a p-channel MOS transistor 31. The transistor 31 is diode-connected and connects to the node PD2 at a source and to the node VDINT at a gate and a drain of the transistor 31.

The third driving circuit 132 and the fourth driving circuit 133 are different from each other in current driving capability. That is, the transistors 30 and 31 are different from each other in current-voltage characteristic. In the present embodiment, a case will be described where, at the same voltage, a larger amount of current flows through the transistor 30 than through the transistor 31.

2.2 Voltages in the Operating State and the Standby State

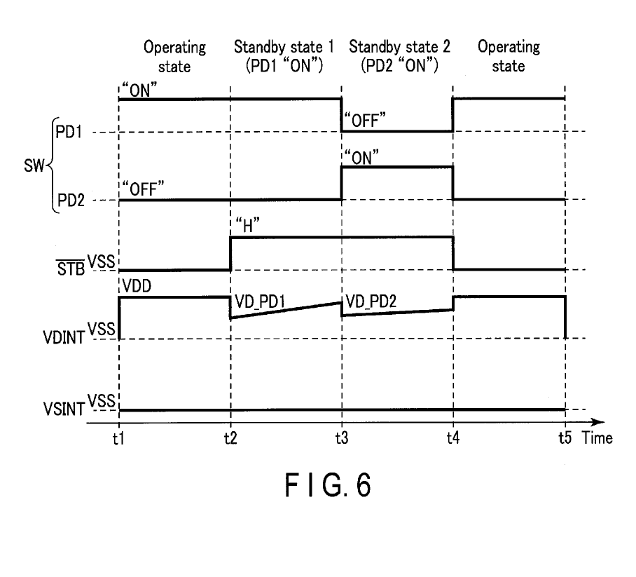

Next, the voltages of the interconnects in the operating state and the standby state will be described using FIG. 6. In an example in FIG. 6, the SRAM 100 is in the operating state during points in time t1 to t2 and during points in time t4 to t5, and is in the standby state during points in time t2 to t4.

As depicted in FIG. 6, first, at point in time t1, the controller 112 sets the signal /STB to the “L” level to set the transistor 17 to the on state. Consequently, the second voltage generator 130 applies the VDD to the node VDINT. The controller 112 selects the node PD1 in the switch circuit 131. In the switch circuit 131, the node PD2 may be selected or neither the node PD1 nor the node PD2 may be selected.

Then, at point in time t2, the SRAM 100 is set to the standby state. In response, the controller 112 sets the signal /STB to the “H” level to set the transistor 17 to the off state. Consequently, a current flows from the power supply node to which the VDD has been applied to the node VDINT via the node PD1 (third driving circuit 132). At this time, a voltage drop at the transistor 30 sets the potential of the node VDINT to VD_PD1. A voltage VD_PD1 and the voltage of the node VSINT (VSS) are in a relation VD_PD1−“the voltage of the node VSINT (VSS)”>Vcell_min. During points in time t2 to t3, the internal temperature decreases to gradually increase the VD_PD1, that is, the Vcell.

Then, at time t3, the controller 112 uses, for example, a change in internal temperature as a trigger to select the node PD2 (fourth driving circuit 133) in the switch circuit 131. At this time, a voltage drop at the transistor 31 sets the voltage of the node VDINT to VD_PD2. As is the case with VD_PD1, the voltage VD_PD2 and the voltage of the node VSINT are in a relation VD_PD2−VSS>Vcell_min. The VD_PD1 and the VD_PD2 are in a relation VD_PD1>VD_PD2 at the same internal temperature.

Then at point in time t4, the SRAM 100 is set to the operating state. In response, the controller 112 sets the signal /STB to the “L” level, and the second voltage generator 130 applies the VDD to the node VDINT as is the case with point in time t1. The controller 112 selects, For example, the node PD1 in the switch element 131.

2.3 Effect of the Present Embodiment

The configuration according to the present embodiment produces an effect similar to the effect of the above-described first embodiment.

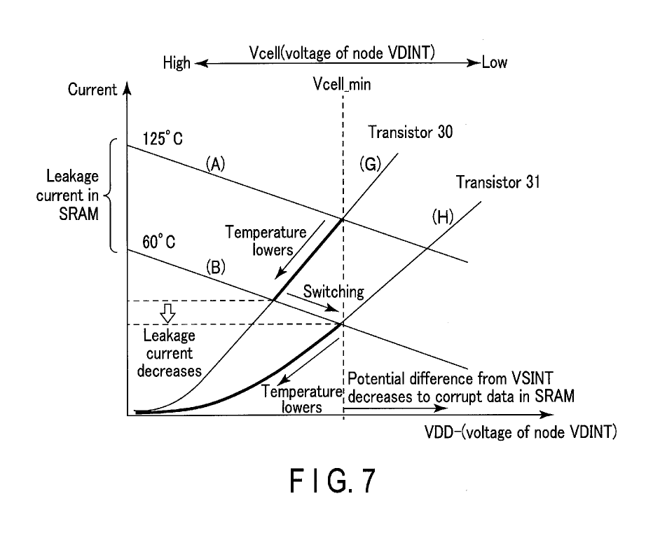

The present effect will be described below using FIG. 7.

FIG. 7 illustrates a relation between a leakage current resulting from application of the present embodiment and a value resulting from subtraction of the voltage of the node VDINT from the VDD. For example, when the internal temperature is between 60° C. and 125° C., the controller 112 selects the transistor 30 (third driving circuit 132, graph (G)), as depicted in FIG. 7. Thus, even at the upper limit temperature, a potential difference equal to or higher than the Vcell_min is applied to the memory cell array 111. VDD−(the voltage of the node VDINT), that is, the voltage of the node VDINT, increases with decreasing internal temperature. When the internal temperature reaches 60° C., the controller 112 switches the transistor 30 to the transistor 31 (fourth driving circuit 133, graph (H)). Then, due to the difference in current driving capability between the transistors 30 and 31, the voltage of the node VDINT decreases. Thus, the use of the transistor 31 enables a reduction in leakage current compared to the use of the transistor 30. As described above, the second voltage generator 130 switches the transistor (that is, the driving circuit) to allow a different voltage to be applied to the memory cell array 111. Therefore, even when the internal temperature decreases, the leakage current can be effectively reduced, in turn reducing the power consumption.

Moreover, in the present embodiment, the voltage of the node VDINT is set lower than the VDD to set the voltage of the back gate of the p-channel MOS transistor higher than the voltage of the source of the p-channel MOS transistor in the memory cell array 111. Therefore, the leakage current can be reduced based on the substrate bias effect. Moreover, in the present embodiment, the second voltage generator 130 switches among the driving circuits with the different current driving capabilities to reduce a variation in Vcell caused by the internal temperature, that is, a variation in the voltage of the node VDINT. This improves the effect of enabling a reduction in leakage current based on the substrate bias effect particularly at low temperature, leading to a reduction in power consumption.

In the present embodiment, the second voltage generator 130 has two driving circuits but may have three or more driving circuits as long as the driving circuits have different current driving capabilities.

Moreover, the switch circuit 131 selects one of the nodes PD1 and PD2. However, the nodes PD1 and PD2 may include separate switch elements. In this case, the nodes PD1 and D2 may be simultaneously selected.

Moreover, the third driving circuit 132 and the fourth driving circuit 134 may each have two or more transistors.

Moreover, the second voltage generator 130 has a current path via the transistor 17 in the operating state. However, this current path may be omitted, and a current path via the transistor 17 may be provided with a driving circuit different from the third and fourth driving circuits in current driving capability. Even in the operating state, the signal /STB may be at the “H” level.

Moreover, the second voltage generator is connected to the power supply node, and the VDD is applied to the second voltage generator. However, the first voltage generator may be applied to a node at a potential different from the VDD.

### 3. Third Embodiment

Next, a semiconductor memory device according to a third embodiment will be described. In the present embodiment, voltage generators are connected to the node VDINT and the node VSINT, respectively. Only differences from the first and second embodiments will be described below.

3.1 Configuration of the SRAM

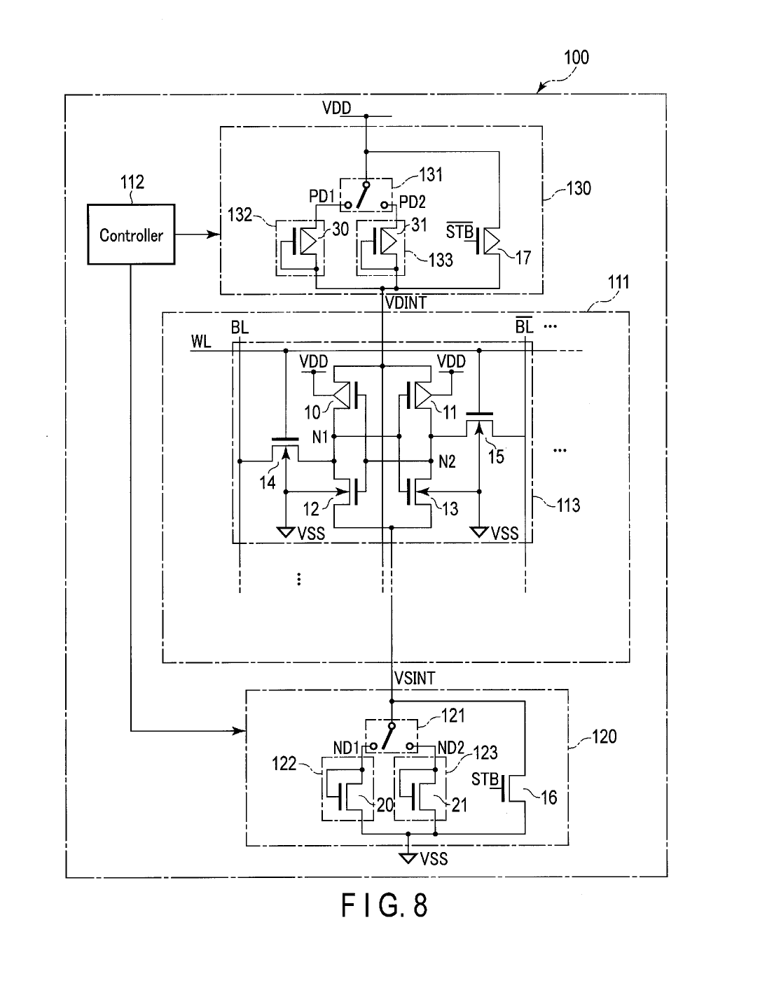

A configuration of the SRAM 100 according to the present embodiment will be described using FIG. 8.

As depicted in FIG. 8, the SRAM 100 includes the second voltage generator 130 coupled between the power supply and the memory cell array 111, and the first voltage generator 120 coupled between the memory cell array 111 and the ground node. The controller 112 controls the first voltage generator 120 and the second voltage generator 130. The configurations of the first voltage generator 120 and the second voltage generator 130 are the same as the configurations in the first and second embodiments.

3.2 Voltages in the Operating State and the Standby State

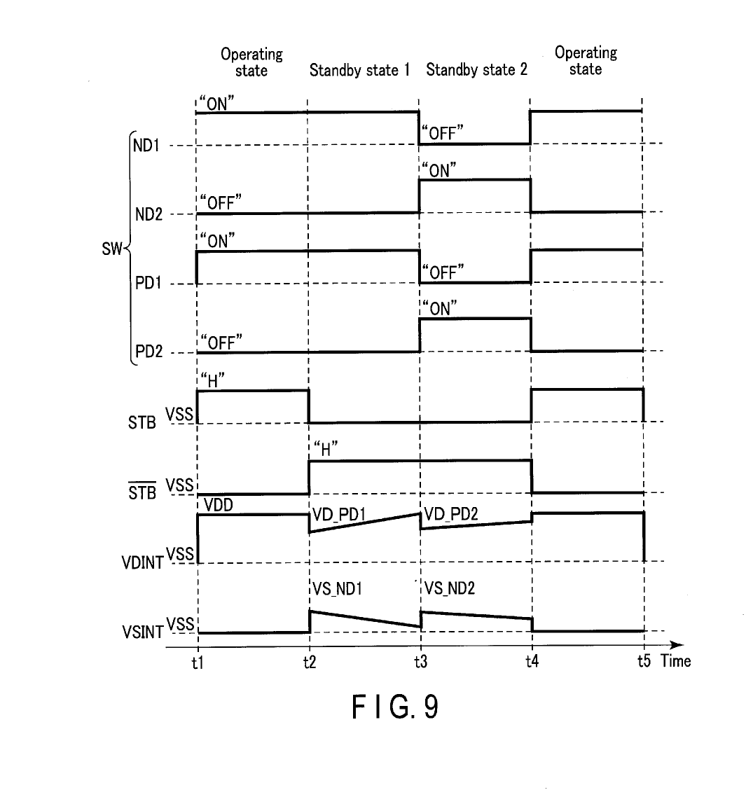

Next, the voltages of the interconnects in the operating state and the standby state will be described using FIG. 9. FIG. 9 is a combination of FIG. 2 and FIG. 6, and the states of the switches and the voltages of the interconnects at each point in time are the same as the corresponding states and voltages in FIG. 2 ad FIG. 6. At point in time t2, the VS_ND1 and the VD_PD1 are in a relation VD_PD1−VS_ND1>Vcell_min. At point in time t3, the VS_ND2 and the VD_PD2 are in a relation VD_PD2−VS_ND2>Vcell_min.

3.3 Effect of the Present Embodiment

The configuration according to the present embodiment produces an effect similar to the effect of the above-described first and second embodiments.

In the present embodiment, the substrate bias effect is used in both the p-channel MOS transistor and the re-channel MOS transistor in the SRAM cell 113 to enable a reduction in leakage current.

### 4. Fourth Embodiment

Next, a semiconductor memory device according to a fourth embodiment will be described. The present embodiment corresponds to the semiconductor memory device according to any of the first to third embodiments that includes a temperature determiner for the memory cell array 111. Only differences from the first to third embodiments will be described below.

4.1 Configuration of the SRAM

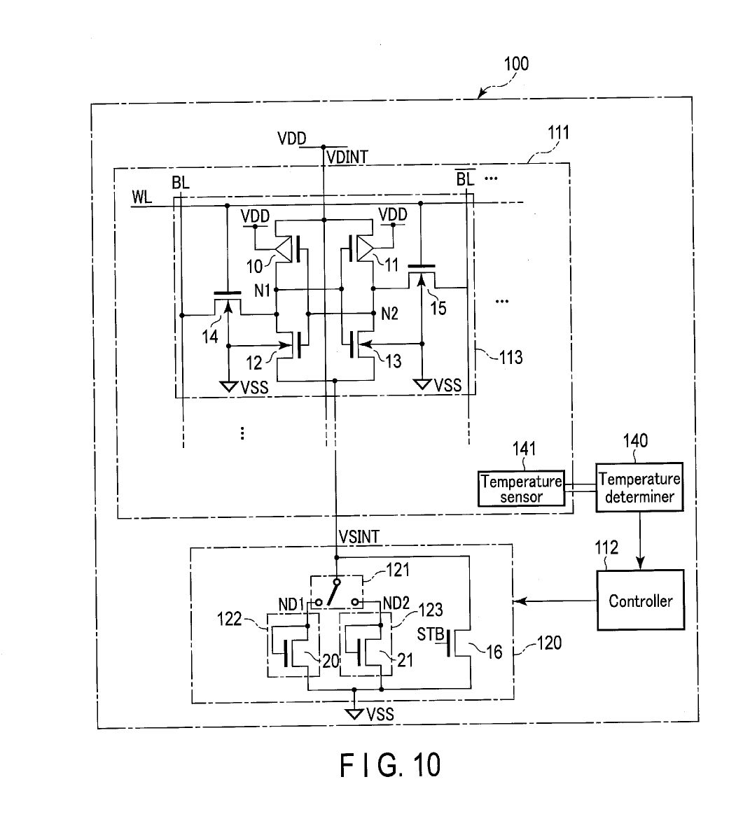

A configuration of the SRAM 100 according to the present embodiment will be described using FIG. 10. FIG. 10 corresponds to FIG. 1 described in the first embodiment and to which a temperature sensor and a temperature determiner are added. Only differences from FIG. 1 will be described.

As depicted in FIG. 10, the SRAM 100 includes a temperature determiner 140 and a temperature sensor 141 provided in the memory cell array 111. The temperature sensor 141 may have a structure that uses, for example, a thermistor or a diode, and the structure of the temperature sensor 141 is not particularly limited. The temperature determiner 140 determines whether the internal temperature is higher than a set temperature (for example, 60° C.), based on a signal obtained from the temperature sensor 141, and transmits the result of the determination to the controller 112. The controller 112 controls the signal STB and the switch circuit 121 based on the state of the memory cell array 111 (operating state or standby state) and the received determination result.

4.2 Voltages in the Operating State and the Standby State

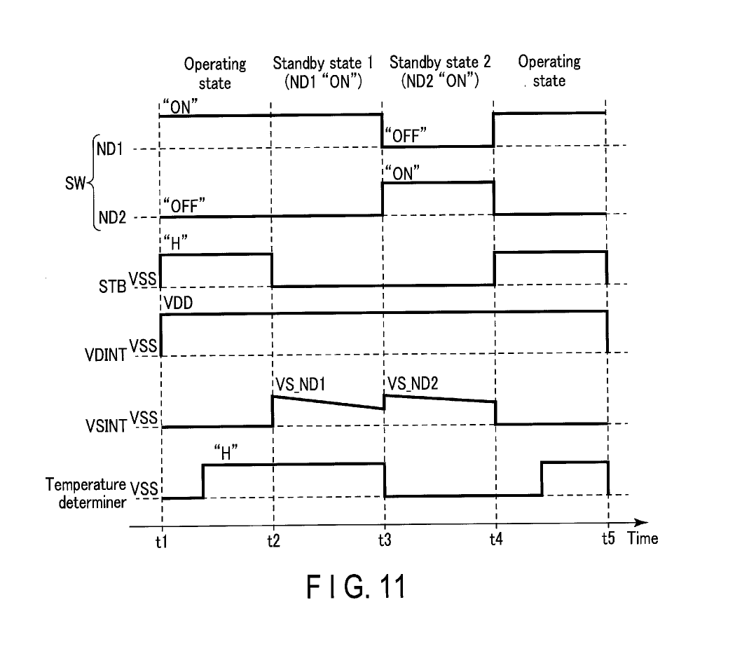

Now, the voltages of the interconnects in the operating state and the standby state will be described using FIG. 11. A difference from FIG. 2 is that a signal from the temperature determiner 140 is added, and the states of the switches and the signals are the same as the corresponding states and signals in FIG. 2. In an example in FIG. 11, the temperature determiner 140 outputs the “H” level when the internal temperature is equal to or higher than the detected temperature (for example, 60° C.) and outputs the “L” level when the internal temperature is lower than the detected temperature.

During points in time t1 to t2, as the internal temperature rises, the output signal from the temperature determiner 140 switches from the “L” level to the “H” level, as depicted in FIG. 11. However, during this period, the SRAM 100 is in the operating state, and thus, the connection to the node VSINT in the first voltage generator 120 is not switched. Then, at point in time t3, when the internal temperature lowers to switch the output signal from the temperature determiner 140 from the “H” level to the “L” level, the controller 112 switches the connection to the node VSINT from the node ND1 to the node ND2 based on the output signal from the temperature determiner 140. Switching from the node ND2 to the node ND1 at point in time t4 is performed based on the state of the memory cell array 111 regardless of the output signal from the temperature determiner 140.

4.3 Effect of the Present Embodiment

To achieve the standby state described in the first to third embodiments as described above, for example, the configuration according to the present embodiment may be applied. For example, in the third embodiment, the controller 112 may switch between the node ND1 and the node ND2 in the first voltage generator 120 and switch between the node PD1 and the node PD2 in the second voltage generator 130 based on the signal from the temperature determiner 140.

### 5. Fifth Embodiment

Next, a semiconductor memory device according to a fifth embodiment will be described. The present embodiment corresponds to the semiconductor memory device according to the first to third embodiment that includes a timer circuit. Only differences from the first to third embodiments will be described below.

5.1 Configuration of the SRAM

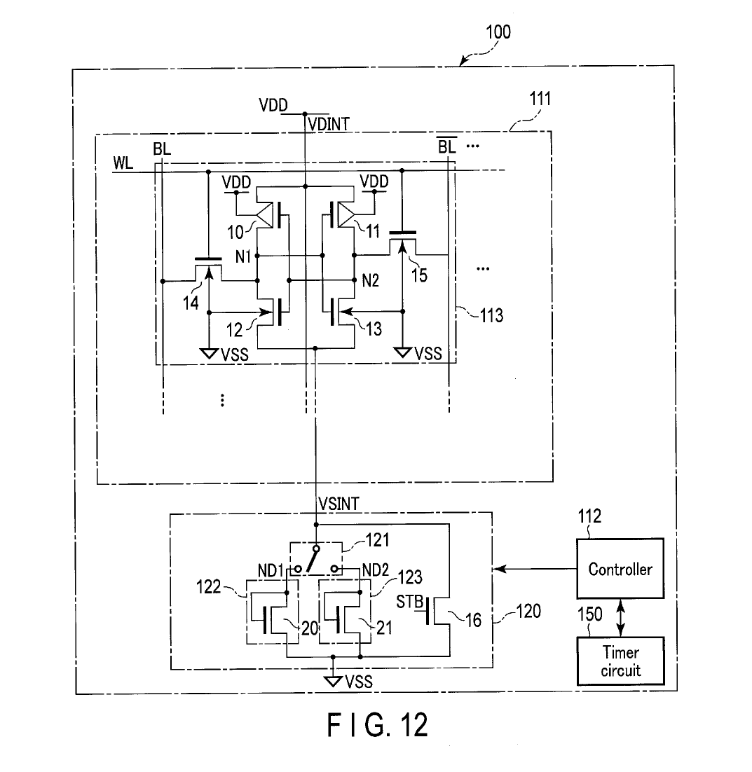

A configuration of the SRAM 100 according to the present embodiment will be described using FIG. 12. FIG. 12 corresponds to FIG. 1 described in the first embodiment and to which the timer circuit is added. Only differences from FIG. 1 will be described.

As depicted in FIG. 12, the SRAM 100 includes a timer circuit 150. Upon receiving, from the controller 112, a signal (for example, the signal STB) indicating that the SRAM shifts from the operating state to the standby state, the timer circuit 150 starts counting. When a set time (count number) is reached, the timer circuit 150 transmits the corresponding result to the controller 112.

5.2 Voltages in the Operating State and the Standby State

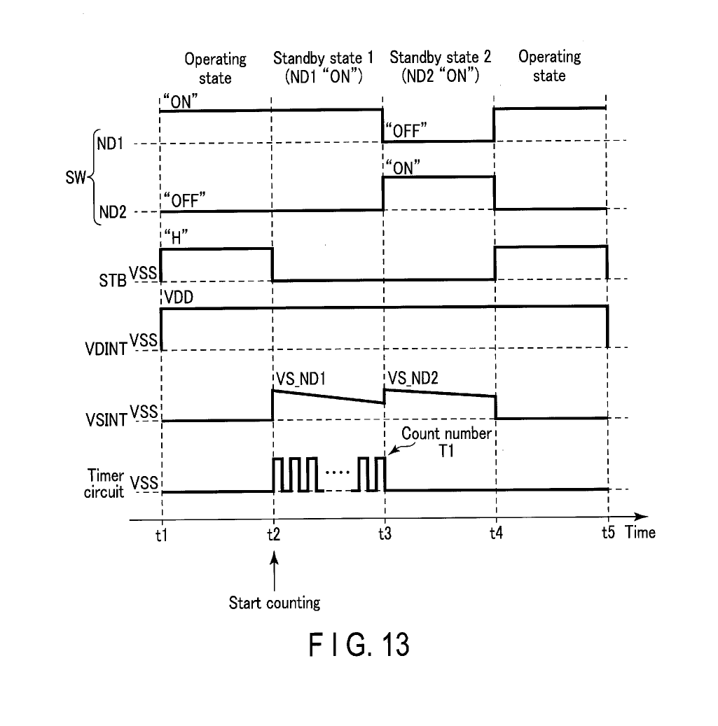

Now, the voltages of the interconnects in the operating state and the standby state will be described using FIG. 13.

As depicted in FIG. 13, at point in time t2, the timer circuit 150 starts counting when the signal STB switches from the “H” level to the “L” level. Then, when the count number reaches T1, the controller 112 switches the connection to the node VSINT from the node ND1 to the node ND2. This timing is point in time t3.

The count number T1 is set to correspond to a time longer than a time needed for the internal temperature to decrease to, for example, 60° C. or lower when the operating state shifts to the standby state.

The timer circuit 150 starts counting when the signal STB switches from the “H” level to the “L” level. However, for example, the timer circuit 150 may be received another control signal from the controller 112 and may start the counting when a given time has elapsed since the reception of the control signal.

5.3 Effect of the Present Embodiment

To achieve the standby state described in the first to third embodiments as described above, for example, the configuration according to the present embodiment may be applied. For example, in the third embodiment, the controller 112 may switch between the node ND1 and the node ND2 in the first voltage generator 120 and switch between the node PD1 and the node PD2 in the second voltage generator 130 based on the signal from the timer circuit 150.

### 6. Sixth Embodiment

Next, a semiconductor memory device according to a sixth embodiment will be described. The present embodiment corresponds to the semiconductor memory device according to any of the first to third embodiments that includes a voltage detector. Only differences from the first to third embodiments will be described below.

6.1 Configuration of the SRAM

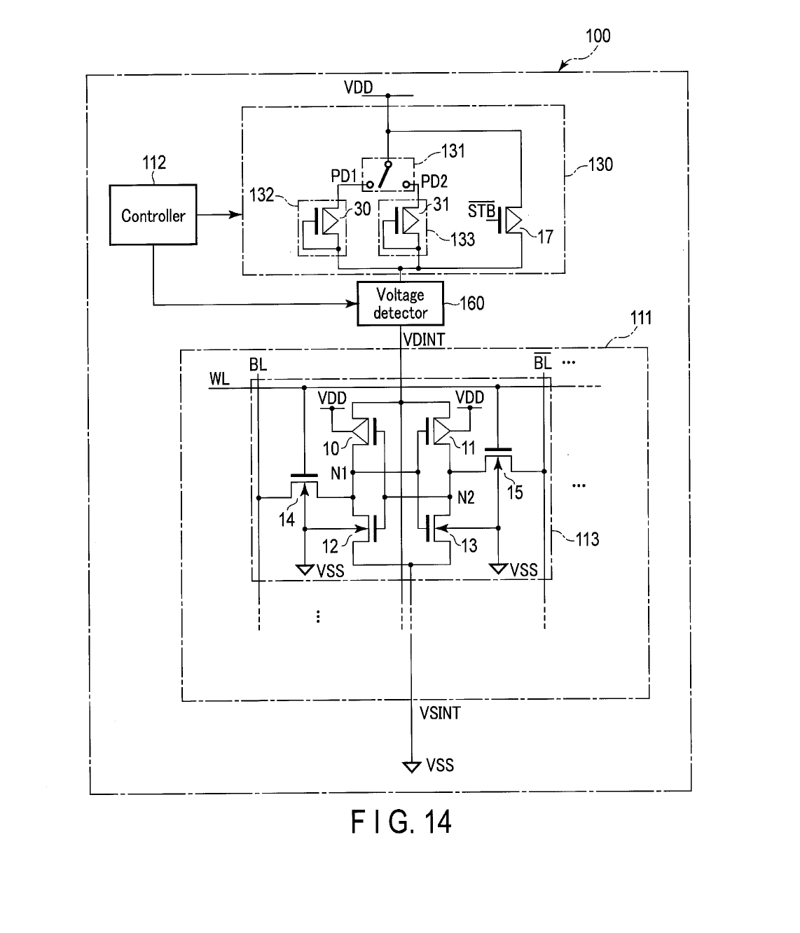

A configuration of the SRAM 100 according to the present embodiment will be described using FIG. 14. FIG. 14 corresponds to FIG. 5 described in the second embodiment and to which the voltage detector is added. Only differences from FIG. 5 will be described.

In the SRAM 100, a voltage detector 160 is connected to the node VDINT as depicted in FIG. 14. The voltage detector 160 detects a voltage applied to the node VDINT by the second voltage generator 130, and transmits the result of the detection to the controller 112.

6.2 Voltages in the Operating State and the Standby State

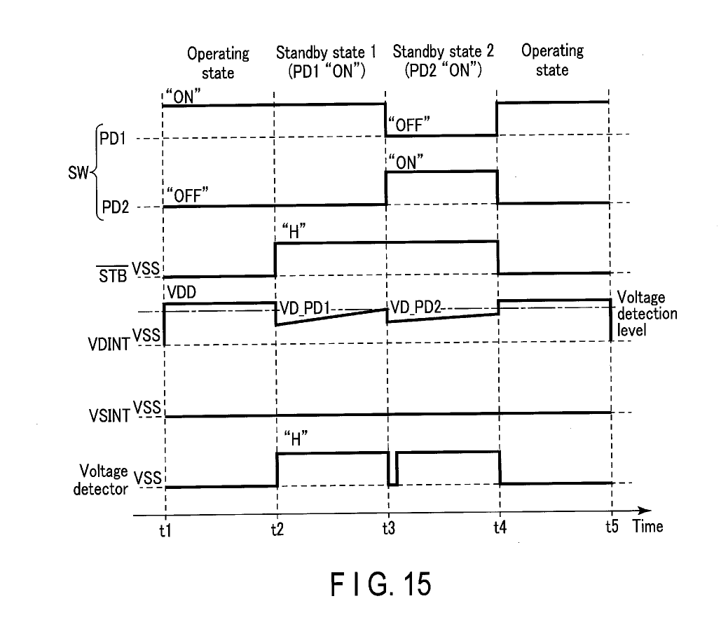

Next, the voltages of the interconnects in the operating state and the standby state will be described using FIG. 15. A difference from FIG. 6 is that a signal from the voltage detector 160 is added, and the states of the switches and the signals are the same as the corresponding states and signals in FIG. 6. In an example in FIG. 15, the voltage detector 160 outputs the “L” level when the voltage of the node VDINT is equal to or higher than a detected level and outputs the “H” level when the voltage is lower than the detected level.

At point in time t2, when the voltage of the node VDINT is lower than the detected level, the output signal from the voltage detector 160 switches from the “L” level to the “H” level. Then, at point in time t3, the VD_PD1 increases up to the detected level or higher, and the output signal from the voltage detector 160 switches from the “H” level to the “L” level. The controller 112 switches the connection to the power supply node from the node PD1 to the node PD2 based on the output signal from the voltage detector 160.

6.3 Effect of the Present Embodiment

To achieve the standby state described in the first to third embodiments as described above, for example, the configuration according to the present embodiment may be applied. For example, in the first embodiment, the voltage detector 160 may be connected to the node VSINT to detect the voltage of the node VSINT. For example, in the third embodiment, the voltages of the nodes VDINT and VSINT may be detected.

Moreover, in the present embodiment, even when the VDD decreases, a potential difference equal to or higher than the Vcell_min may be applied to the memory cell array 111. For example, in FIG. 7, when the VDD decreases with the internal temperature at 60° C. or lower and with the transistor 31 selected by the controller 112, the controller 112 switches from the transistor 31 to the transistor 30 to increase the voltage of the node VDINT to allow a potential difference equal to or higher than the Vcell_min to be applied to the Vcell. Therefore, even when the power supply voltage VDD decreases, the loss of data held by the memory cell array 111 is suppressed, allowing the reliability of data in the standby state to be enhanced.

### 7. Modifications and the Like

The semiconductor memory device according to the above-described embodiments includes: a memory cell array (111 in FIG. 1); a first power supply line (VSINT in FIG. 1); a second power supply line (VDINT in FIG. 1); a first voltage generator (120 in FIG. 1); and a first interconnect (ground node in FIG. 1). The memory cell array includes the SRAM cell (113 in FIG. 1). The first power supply line applies a low-voltage-side power supply voltage to the SRAM cell. The second power supply line applies a high-voltage-side power supply voltage that is higher than the low-voltage-side power supply voltage to the SRAM cell. The first voltage generator applies a voltage to one of the first and second power supply lines. The first interconnect applies a first voltage (VSS in FIG. 1) to the first voltage generator. The first voltage generator includes: a first circuit (122 in FIG. 1); a second circuit (123 in FIG. 1); and a first switch circuit (121 in FIG. 1) capable of switching between coupling of the first circuit between the one of the first and second power supply lines and the first interconnect and coupling of the second circuit between the one of the first and second power supply lines and the first interconnect. The first circuit includes a diode-connected first transistor (20 in FIG. 1) coupled between the one of the first and second power supply lines and the first interconnect. The second circuit includes a diode-connected second transistor (21 in FIG. 1) coupled between the one of the first and second power supply lines and the first interconnect. A driving capability of the first transistor is different from a driving capability of the second transistor. When the SRAM cell is in an operating state, the first voltage generator applies the first voltage to the one of the first and second power supply lines. When the SRAM cell is in a standby state, the first voltage generator applies the first voltage to the one of the first and second power supply lines via the first circuit or the second circuit to apply a second voltage (VS_ND1 in FIG. 2) or a third voltage (VS_ND2 in FIG. 2) to the one of the first and second power supply lines.

The application of the above-described embodiments allows provision of a semiconductor memory device that enables a reduction in power consumption. The embodiments are not limited to the above-described ones and various medications may be made to the embodiments.

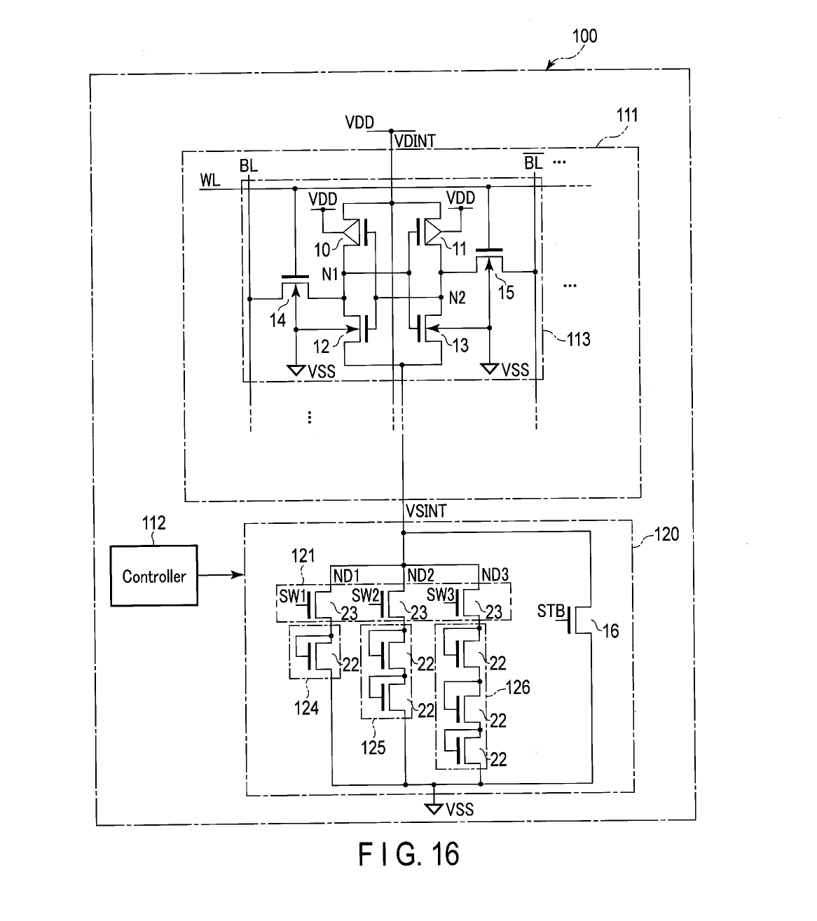

For example, in the above-described embodiments, the first voltage generator 120 may include three driving circuits, and different numbers of transistors may be connected in series with the respective three driving circuits. Such an example is depicted in FIG. 16.

As depicted in FIG. 16, the first voltage generator 120 includes a switch circuit 121 and a fifth driving circuit 124, a sixth driving circuit 125, and a seventh driving circuit 126 that are connected to the switch circuit 121. The switch circuit 121 includes three n-channel MOS transistors 23. The three transistors 23 controls, based on signals SW1 to SW3 input to respective gates, connection between the node ND1 and the fifth driving circuit 124, the node ND2 and the sixth driving circuit 125, and the node ND3 and the seventh driving circuit 126. The fifth driving circuit 124 includes one diode-connected n-channel MOS transistor 22. The sixth driving circuit 125 includes two diode-connected transistors 22 that are connected together in series. The seventh driving circuit 126 includes three diode-connected transistors 22 that are connected together in series. The fifth to seventh driving circuits 124 to 126 include different numbers of transistors 22 connected together in series and thus have different current driving capabilities. In the standby state, the controller 112 controls the signals SW1 to SW3 input to the gates of the transistors 23 in the switch circuit 121 to select from the fifth to seventh driving circuits 124 to 126. At this time, the controller 112 may simultaneously select a plurality of driving circuits. For example, the controller 112 may simultaneously select the fifth driving circuit 124 and the sixth driving circuit 125 or simultaneously select the fifth to seventh driving circuits 124 to 126. In the second and third embodiments, the second voltage generator 130 may be similarly configured.

Moreover, in the above-described embodiments, the switch circuit 121 is coupled between the node VSINT and the driving circuit. However, the switch circuit 121 may be coupled between the driving circuit and the ground node. Moreover, the switch circuit 131 is coupled between the power supply node that transfers the VDD and the driving circuit. However, the switch circuit 131 may be coupled between the driving circuit and the node VDINT.

Moreover, three or more of the above-described embodiments may be combined together for application. For example, the temperature determiner 140 of the fourth embodiment and the voltage detector 160 of the sixth embodiment may be applied to the semiconductor memory device according to the third embodiment.

Moreover, the term “connect” or “couple” in the above-described embodiments also include indirect connection with any other component such as a transistor or a resistor interposed between objects.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including an SRAM (static random access memory) cell;
a first power supply line applying a low-voltage-side power supply voltage to the SRAM cell;
a second power supply line applying a high-voltage-side power supply voltage, which is higher than the low-voltage-side power supply voltage, to the SRAM cell;
a first voltage generator applying a voltage to one of the first and second power supply lines; and
a first interconnect applying a first voltage to the first voltage generator,
wherein the first voltage generator includes;
a first circuit;
a second circuit; and
a first switch circuit capable of switching between coupling of the first circuit between the one of the first and second power supply lines and the first interconnect and coupling of the second circuit between the one of the first and second power supply lines and the first interconnect,
the first circuit includes a diode-connected first transistor coupled between the one of the first and second power supply lines and the first interconnect,
the second circuit includes a diode-connected second transistor coupled between the one of the first and second power supply lines and the first interconnect,
a driving capability of the first transistor is different from a driving capability of the second transistor,
when the SRAM cell is in an operating state, the first voltage generator applies the first voltage to the one of the first and second power supply lines, and
when the SRAM cell is in a standby state, the first voltage generator applies the first voltage to the one of the first and second power supply lines via the first circuit or the second circuit to apply a second voltage or a third voltage to the one of the first and second power supply lines.

2. The device according to claim 1, wherein
the driving capability of the first transistor is higher than the driving capability of the second transistor,
when the SRAM cell is in the standby state, the first voltage generator applies the second voltage via the first circuit when a temperature of the SRAM cell is higher than a first temperature, and
the first voltage generator applies the third voltage via the second circuit when the temperature of the SRAM cell is lower than the first temperature.

3. The device according to claim 1, wherein
the driving capability of the first transistor is higher than the driving capability of the second transistor, and
when the SRAM cell is in the standby state, a current flowing through the first transistor when the first voltage is applied to the one of the first and second power supply lines via the first circuit is larger than a current flowing through the second transistor when the first voltage is applied to the one of the first and second power supply lines via the second circuit.

4. The device according to claim 1, wherein
based on a switching operation of the first switch circuit,
the first voltage is applied via the first circuit to apply the second voltage, or
the first voltage is applied via the second circuit to apply the third voltage.

5. The device according to claim 1, wherein
the first voltage generator further includes a third transistor coupled between the one of the first and second power supply lines and the first interconnect,
when the SRAM cell is in the operating state, the third transistor having a higher driving capability than the first transistor and the second transistor turns on to apply the first voltage to the one of the first and second power supply lines, and
when the SRAM cell is in the standby state, the third transistor turn off to apply the second voltage or the third voltage to the one Of the first and second power supply lines.

6. The device according to claim 1, wherein
when the one of the first and second power supply lines is the first power supply line, the second voltage and the third voltage are higher than the first voltage, and
when the one of the first and second power supply lines is the second power supply line, the second voltage and the third voltage are lower than the first voltage.

7. The device according to claim 1, wherein
the one of the first and second power supply lines is the first power supply line, the first voltage is a ground voltage, and the first transistor and the second transistor are n-channel MOS transistors.

8. The device according to claim 1, wherein
the one of the first and second power supply lines is the second power supply line, the first voltage is a power supply voltage, and the first transistor and the second transistor are p-channel MOS transistors.

9. The device according to claim 1, wherein
The first transistor and the second transistor are different from each other in size.

10. The device according to claim 1, wherein
in the operating state, a data write operation or a data read operation is performed in the memory cell array, and
in the standby state, neither of the write and read operations are performed in the memory cell array and any SRAM cell holds the data.

11. The device according to claim 1, further comprising:
a second voltage generator applying a voltage to other of the first and second power supply lines; and
a second interconnect applying a fourth voltage to the second voltage generator,
wherein the first voltage generator further includes a third transistor coupled between the one of the first and second power supply lines and the first interconnect,
the second voltage generator includes:
a third circuit;
a fourth circuit; and
a second switch circuit switching between coupling of the third circuit between the other of the first and second power supply lines and the second interconnect and coupling of the fourth circuit between the other of the first and second power supply lines and the second interconnect,
the third circuit includes a diode-connected fourth transistor coupled between the other of the first and second power supply lines and the second interconnect,
the fourth circuit includes a diode-connected fifth transistor coupled between the other of the first and second power supply lines and the second interconnect,
a driving capability of the fourth transistor is different from a driving capability of the fifth transistor,
when the SRAM cell is in the operating state, the second voltage generator applies the fourth voltage to the other of the first and second power supply lines, and
when the SRAM cell is in the standby state, the second voltage generator applies the fourth voltage to the other of the first and second power supply lines via the third circuit or the fourth circuit to apply a fifth voltage or a sixth voltage to the other of the first and second power supply lines.

12. The device according to claim 1, further comprising a temperature determiner determining a temperature of the memory cell array,
wherein the first voltage generator switches the first switch circuit in accordance with the temperature determiner.

13. The device according to claim 1, further comprising a timer circuit measuring an elapsed time when the SRAM cell shifts from the operating state to the standby state,
wherein the first voltage generator switches the first switch circuit in accordance with the timer circuit.

14. The device according to claim 1, further comprising a voltage detector detecting a voltage of the one of the first and second power supply lines,
wherein the first voltage generator switches the first switch circuit in accordance with the voltage detector.

15. The device according to claim 11, wherein
according to a switching of the second switch circuit,
the fourth voltage is applied via the third circuit to apply the fifth voltage, or
the fourth voltage is applied via the fourth circuit to apply the sixth voltage.

16. The device according to claim 11, wherein
the second voltage generator further includes a fifth transistor coupled between the other of the first and second power supply lines and the second interconnect,
when the SRAM cell is in the operating state, the fifth transistor having a higher driving capability than the third transistor and the fourth transistor is set to a conductive state to apply the fourth voltage to the other of the first and second power supply lines, and
when the SRAM cell is in the standby state, the fifth transistor is set to a non-conductive state to apply the fifth voltage or the sixth voltage to the other of the first and second power supply lines.

17. The device according to claim 11, wherein
when the other of the first and second power supply lines is the second power supply line, the fifth voltage and the sixth voltage are lower than the fourth voltage, and
when the other of the first and second power supply lines is the first power supply line, the firth voltage and the sixth voltage are higher than the fourth voltage.

18. The device according to claim 11, wherein
the one of the first and second power supply lines is the first power supply line, the first voltage is a ground voltage, and the first transistor and the second transistor are n-channel MOS transistors, and
the other of the first and second power supply lines is the second power supply line, the fourth voltage is a power supply voltage, and the third transistor and the fourth transistor are p-channel MOS transistors.

19. A semiconductor memory device comprising:
a memory cell array including an SRAM (static random access memory) cell;
a first power supply line applying a low-voltage-side power supply voltage to the SRAM cell;
a second power supply line applying a high-voltage-side power supply voltage which is higher than the low-voltage-side power supply voltage to the SRAM cell;
a first voltage generator applying a voltage to one of the first and second power supply lines; and
a first interconnect applying a first voltage to the first voltage generator,
wherein the first voltage generator includes a first circuit;
a second circuit; and
a first switch circuit connectable the first circuit or the second circuit between the one of the first and second power supply lines and the first interconnect,
the first circuit includes at least one diode-connected first transistor coupled between the one of the first and second power supply lines and the first interconnect,
the second circuit includes at least one diode-connected second transistor coupled between the one of the first and second power supply lines and the first interconnect,
a number of the first transistors provided in the first circuit is different from a number of second transistors provided in the second circuit,
when the SRAM cell is in an operating state, the first voltage generator applies the first voltage to the one of the first and second power supply lines, and
when the SRAM cell is in a standby state, the first voltage generator switches coupling of the first circuit or the second circuit to the one of the first and second power supply lines to apply a second voltage or a third voltage to the one of the first and second power supply lines.

20. The device according to claim 19, wherein
the first switch circuit includes a third transistor coupling the first circuit between the one of the first and second power supply lines and the first interconnect; and
a fourth transistor coupling the second circuit between the one of the first and second power supply lines and the first interconnect.
